(19) United States
(12) Patent Application Publication
(10) Pub. No.: US 2013/0027154 A1
(43) Pub. Date: Jan. 31, 2013

(54) FILTER CAPABLE OF ADJUSTING FREQUENCY RESPONSE

(71) Applicant: Hsin-Ta Wu, Taipei City (TW)

(72) Inventor: Hsin-Ta Wu, Taipei City (TW)

(21) Appl. No.: 13/237,961

(22) Filed: Sep. 21, 2011

(30) Foreign Application Priority Data
Jul. 28, 2011 (TW) 100126772

(51) Int. Cl. H03H 7/00

(52) U.S. Cl. 333/174; 333/175

(57) ABSTRACT

A filter includes a first varactor with a first end electrically connected to a signal input end, a second varactor with a first end electrically connected to a second end of the first varactor, and a second end electrically connected to ground, and an inductor with a first end electrically connected to the second end of the first varactor, and a second end electrically connected to ground. The filter is capable of adjusting its frequency response by changing capacitance of the first varactor and/or the second varactor.

### BACKGROUND OF THE INVENTION

1. Field of the Invention

The present invention relates to a filter, and more particularly, to a filter capable of adjusting frequency response.

2. Description of the Prior Art

Please refer to FIG. 1. FIG. 1 is a diagram showing a notch filter 100 of the prior art. As shown in FIG. 1, the notch filter 100 comprises a capacitor C, a varactor Cv, and an inductor L. A first end of the capacitor C is electrically connected to a signal input end IN. A first end of the varactor Cv is electrically connected to a second end of the capacitor C. A second end of the varactor Cv is electrically connected to ground. A first end of the inductor L is electrically connected to the second end of the capacitor C. A second end of the inductor L is electrically connected to ground.

Please refer to FIG. 2. FIG. 2 is a diagram showing a frequency response of impedance of the notch filter 100 of FIG. 1. A frequency fp located at a peak of a frequency response curve of the impedance of the notch filter 100 is a pole frequency. A frequency fz located at a bottom of the frequency response curve of the impedance of the notch filter 100 is a zero frequency. The notch filter 100 allows required signals with frequencies around the pole frequency fp to pass through, and filters out unwanted signals with frequencies around the zero frequency fz, such that the notch filter 100 is able to filter input signals from the signal input end IN. The pole frequency fp and the zero frequency fz of the notch filter can be determined according to the following equations:

$$\begin{matrix}{f}_{z} = \frac{1}{2 π \sqrt{Lv \cdot ( C 1 + C 2 )}} & equation ( 1 ) \\ {f}_{p} = \frac{1}{2 π \sqrt{Lv \cdot C 2}} & equation ( 2 )\end{matrix}$$

wherein Lv is an inductance value of the inductor L, C1 is a capacitance value of an upper side of the notch filter 100 (that is, a capacitance value of the capacitor C), and C2 is a capacitance value of a lower side of the notch filter 100 (that is, a capacitance value of the varactor Cv). The pole frequency fp and the zero frequency fz can be adjusted by changing the capacitance of the varactor Cv in order to set positions of the pole frequency fp and the zero frequency fz. However, according to equation (1) and equation (2), both the pole frequency fp and the zero frequency fz change when the capacitance of the varactor Cv changes. The pole frequency fp or the zero frequency fz of the notch filter 100 of the prior art can not be changed independently in order to move the pole frequency fp and the zero frequency fz to required positions respectively. Therefore, the notch filter 100 of the prior art imposes limitations on design.

### SUMMARY OF THE INVENTION

The present invention provides a filter capable of adjusting frequency response. The filter comprises a first varactor with a first end electrically connected to a signal input end, a second varactor with a first end electrically connected to a second end of the first varactor and a second end electrically connected to ground, and an inductor with a first end electrically connected to the second end of the first varactor and a second end electrically connected to ground.

The present invention further provides another filter capable of adjusting frequency response, which comprises a varactor, at least one capacitance adjusting unit, and an inductor. A first end of the varactor is electrically connected to a signal input end. The capacitance adjusting unit comprises a capacitor and a switch. A first end of the capacitor is electrically connected to a second end of the varactor. A first end of the switch is electrically connected to a second end of the capacitor, and a second end of the switch is electrically connected to ground. The switch is for electrically connecting the second end of the capacitor to ground when the switch is turned on. A first end of the inductor is electrically connected to the second end of the first varactor, and a second end of the inductor is electrically connected to ground.

The present invention further provides another filter capable of adjusting frequency response, which comprises a first varactor, a second varactor, at least one first capacitance adjusting unit, at least one second capacitance adjusting unit, and an inductor. A first end of the first varactor is electrically connected to a signal input end. A first end of the second varactor is electrically connected to a second end of the first varactor, and a second end of the second varactor is electrically connected to ground. The first capacitance adjusting unit comprises a first capacitor and a first switch. A first end of the first capacitor is electrically connected to the signal input end. A first end of the first switch is electrically connected to a second end of the first capacitor, and a second end of the first switch is electrically connected to the second end of the first varactor. The first switch is for electrically connecting the second end of the first capacitor to the second end of the first varactor when the first switch is turned on. The second capacitance adjusting unit comprises a second capacitor and a second switch. A first end of the second capacitor is electrically connected to the first end of the second varactor. A first end of the second switch is electrically connected to a second end of the second capacitor, and a second end of the second switch is electrically connected to ground. The second switch is for electrically connecting the second end of the second capacitor to ground when the second switch is turned on. A first end of the inductor is electrically connected to the second end of the first varactor, and a second end of the inductor is electrically connected to ground.

The present invention further provides another filter capable of adjusting frequency response, which comprises a first varactor, a second varactor, at least one capacitance adjusting unit, and an inductor. A first end of the first varactor is electrically connected to a signal input end. A first end of the second varactor is electrically connected to a second end of the first varactor, and a second end of the second varactor is electrically connected to ground. The capacitance adjusting unit comprises a capacitor and a switch. A first end of the capacitor is electrically connected to the signal input end. A first end of the switch is electrically connected to a second end of the capacitor, and a second end of the switch is electrically connected to the second end of the first varactor. The switch is for electrically connecting the second end of the capacitor to the second end of the first varactor when the switch is turned on. A first end of the inductor is electrically connected to the second end of the first varactor, and a second end of the inductor is electrically connected to ground.

The present invention further provides another filter capable of adjusting frequency response, which comprises a plurality of capacitance adjusting units, a varactor, and an inductor. Each capacitance adjusting unit comprises a capacitor and a switch. A first end of the capacitor is electrically connected to a signal input end. A first end of the switch is electrically connected to a second end of the capacitor. The switch is for electrically connecting the second end of the capacitor to a second end of the switch when the switch is turned on. A first end of the varactor is electrically connected to the second end of the switch, and a second end of the varactor is electrically connected to ground. A first end of the inductor is electrically connected to the second end of the switch, and a second end of the inductor is electrically connected to ground.

The present invention further provides another filter capable of adjusting frequency response, which comprises a plurality of first capacitance adjusting units, a plurality of second capacitance adjusting units, and an inductor. Each first capacitance adjusting unit comprises a first capacitor and a first switch. A first end of the first capacitor is electrically connected to a signal input end. A first end of the first switch is electrically connected to a second end of the first capacitor. The first switch is for electrically connecting the second end of the first capacitor to a second end of the first switch when the first switch is turned on. Each second capacitance adjusting unit comprises a second capacitor and a second switch. A first end of the second capacitor is electrically connected to the second end of the first switch. A first end of the second switch is electrically connected to a second end of the second capacitor, and a second end of the second switch is electrically connected to ground. The second switch is for electrically connecting the second end of the second capacitor to ground when the second switch is turned on. A first end of the inductor is electrically connected to the second end of the first switch, and a second end of the inductor is electrically connected to ground.

In addition, the present invention further provides a method for adjusting frequency response of a filter. The filter comprises a first capacitor, a second capacitor, and an inductor. A first end of the first capacitor is electrically connected to a signal input end. A first end of the second capacitor is electrically connected to a second end of the first capacitor, and a second end of the second capacitor is electrically connected to ground. A first end of the inductor is electrically connected to the second end of the first capacitor, and a second end of the inductor is electrically connected to ground. The method comprises measuring a gain of the filter at a particular frequency, and adjusting a capacitance of the first capacitor according to the gain of the filter at the particular frequency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a notch filter of the prior art.

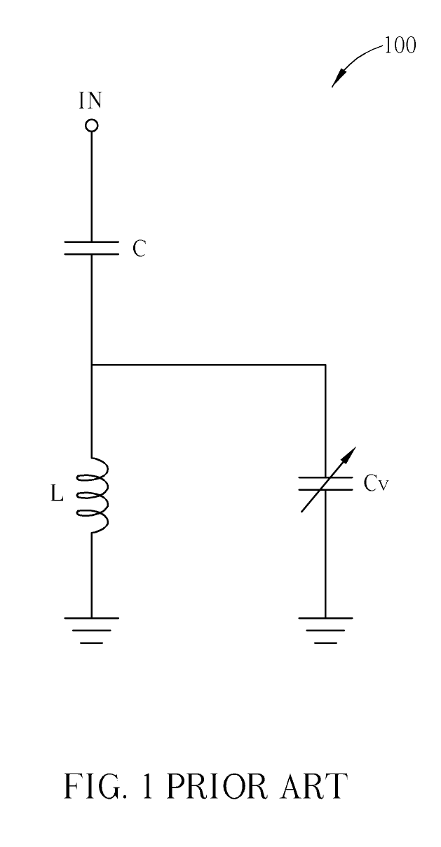

FIG. 2 is a diagram showing frequency response of impedance of the notch filter of FIG. 1.

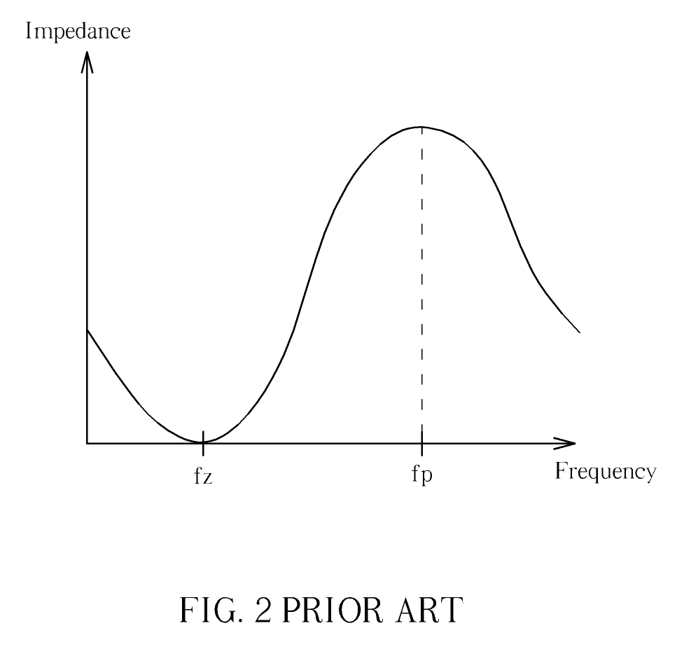

FIG. 3 is a diagram showing a first embodiment of a filter of the present invention.

FIG. 4 is a diagram showing a second embodiment of a filter of the present invention.

FIG. 5 is a diagram showing a third embodiment of a filter of the present invention.

FIG. 6 is a diagram showing a fourth embodiment of a filter of the present invention.

FIG. 7 is a diagram showing a fifth embodiment of a filter of the present invention.

FIG. 8 is a diagram showing a sixth embodiment of a filter of the present invention.

FIG. 9 is a diagram showing a seventh embodiment of a filter of the present invention.

FIG. 10 is a diagram showing the filter of the present invention adjusting a frequency response of a high frequency band of a low noise block.

FIG. 11 is a diagram showing the filter of the present invention adjusting a frequency response of a low frequency band of the low noise block.

### DETAILED DESCRIPTION

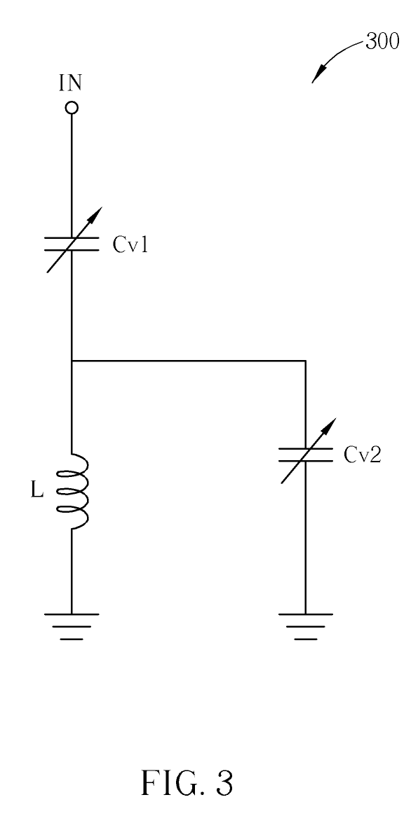

Please refer to FIG. 3. FIG. 3 is a diagram showing a first embodiment of a filter 300 of the present invention. As shown in FIG. 3, the filter 300 comprises a first varactor Cv1, a second varactor Cv2, and an inductor L. A first end of the first varactor Cv1 is electrically connected to a signal input end IN. A first end of the second varactor Cv2 is electrically connected to a second end of the first varactor Cv1, and a second end of the second varactor Cv2 is electrically connected to ground. A first end of the inductor L is electrically connected to the second end of the first varactor Cv1, and a second end of the inductor L is electrically connected to ground. According to the above arrangement, because a capacitance of the first varactor Cv1 is adjustable, the zero frequency fz can be changed independently by adjusting the capacitance of the first varactor Cv1. That is, the pole frequency fp and the zero frequency fz can be changed independently for moving the pole frequency fp and the zero frequency fz to required positions respectively.

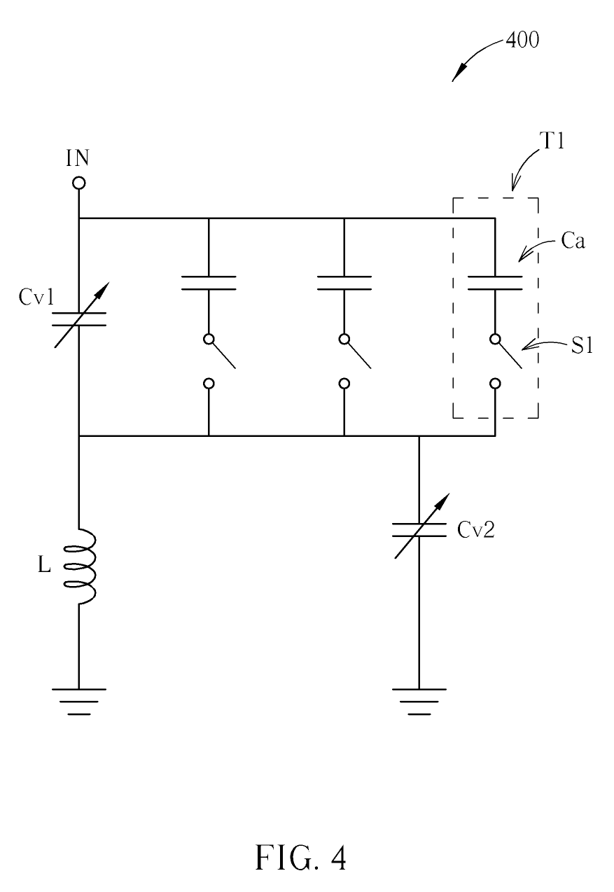

Please refer to FIG. 4. FIG. 4 is a diagram showing a second embodiment of a filter 400 of the present invention. As shown in FIG. 4, the filter 400 further comprises a plurality of first capacitance adjusting units T1. The first capacitance adjusting unit T1 comprises a first capacitor Ca and a first switch S1. A first end of the first capacitor Ca is electrically connected to a signal input end IN. A first end of the first switch S1 is electrically connected to the second end of the first capacitor. A second end of the first switch S1 is electrically connected to the second end of the first varactor Cv1. The first switch S1 is for electrically connecting the second end of the first capacitor Ca to the second end of the first varactor Cv1. According to the above arrangement, the first varactor Cv1 can be utilized to fine tune a capacitance of an upper side of the filter 400, and the first capacitance adjusting unit T1 can be utilized to coarse tune the capacitance of the upper side of the filter 400 by controlling on and off states of the first switch S1 of the first capacitance adjusting unit T1. The second varactor Cv2 can be utilized to fine tune a capacitance of a lower side of the filter 400.

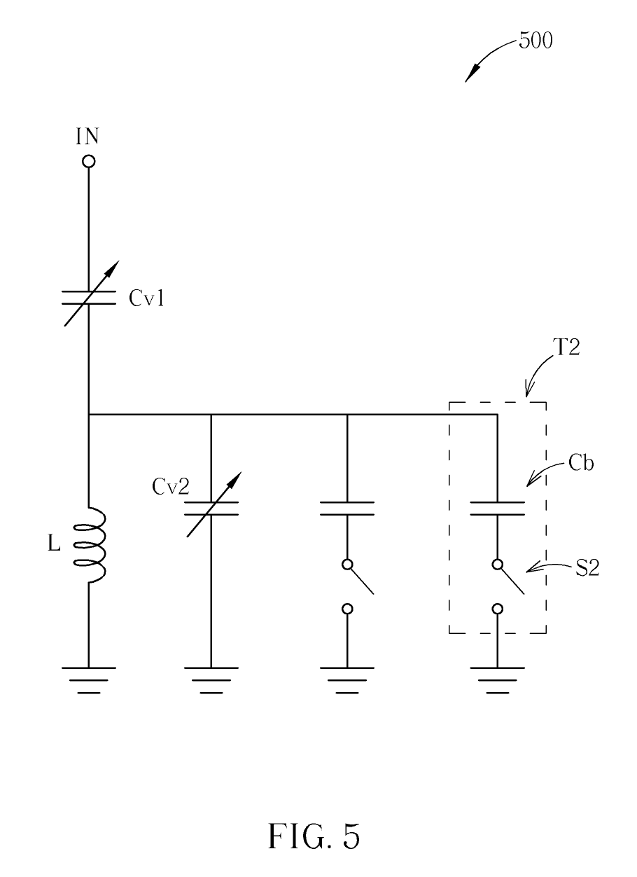

Please refer to FIG. 5. FIG. 5 is a diagram showing a third embodiment of a filter 500 of the present invention. As shown in FIG. 5, the filter 500 further comprises a plurality of second capacitance adjusting units T2. The second capacitance adjusting unit T2 comprises a second capacitor Cb and a second switch S2. A first end of the second capacitor Cb is electrically connected to the second end of the first varactor Cv1. A first end of the second switch S2 is electrically connected to a second end of the second capacitor Cb, and a second end of the second switch S2 is electrically connected to ground. The second switch S2 is for electrically connecting the second capacitor Cb to ground when the second switch S2 is turned on. According to the above arrangement, the first varactor Cv1 can be utilized to fine tune a capacitance of an upper side of the filter 500. The second varactor Cv2 can be utilized to fine tune a capacitance of a lower side of the filter 500, and the second capacitance adjusting unit T2 can be utilized to coarse tune the capacitance of the lower side of the filter 500 by controlling on and off states of the second switch S2 of the second capacitance adjusting unit T2.

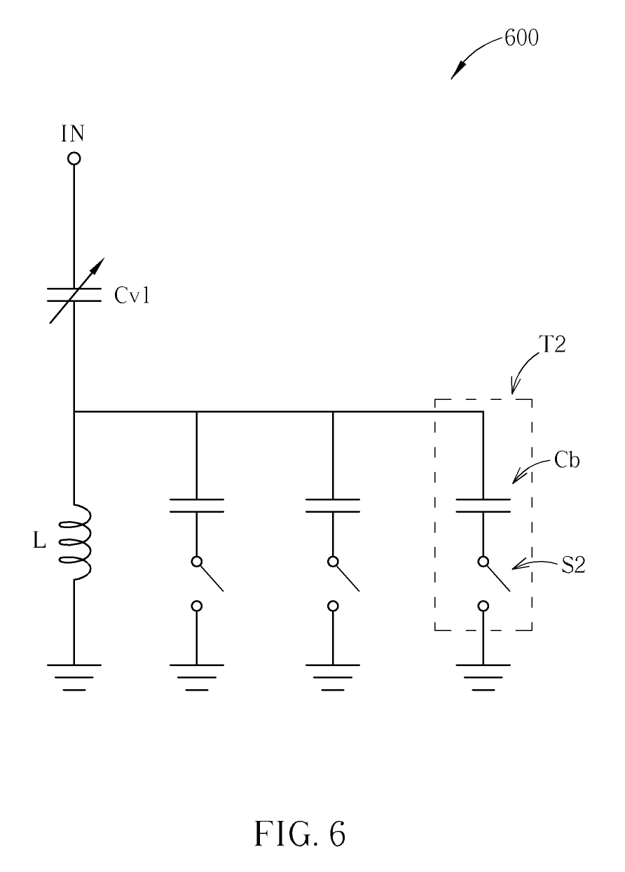

Please refer to FIG. 6. FIG. 6 is a diagram showing a fourth embodiment of a filter 600 of the present invention. As shown in FIG. 6, the filter 600 comprises a first varactor Cv1, a plurality of second capacitance adjusting units T2, and an inductor L. According to the above arrangement, the first varactor Cv1 can be utilized to fine tune a capacitance of an upper side of the filter 600, and the second capacitance adjusting unit T2 can be utilized to coarse tune a capacitance of a lower side of the filter 600 by controlling on and off states of the second switch S2 of the second capacitance adjusting unit T2.

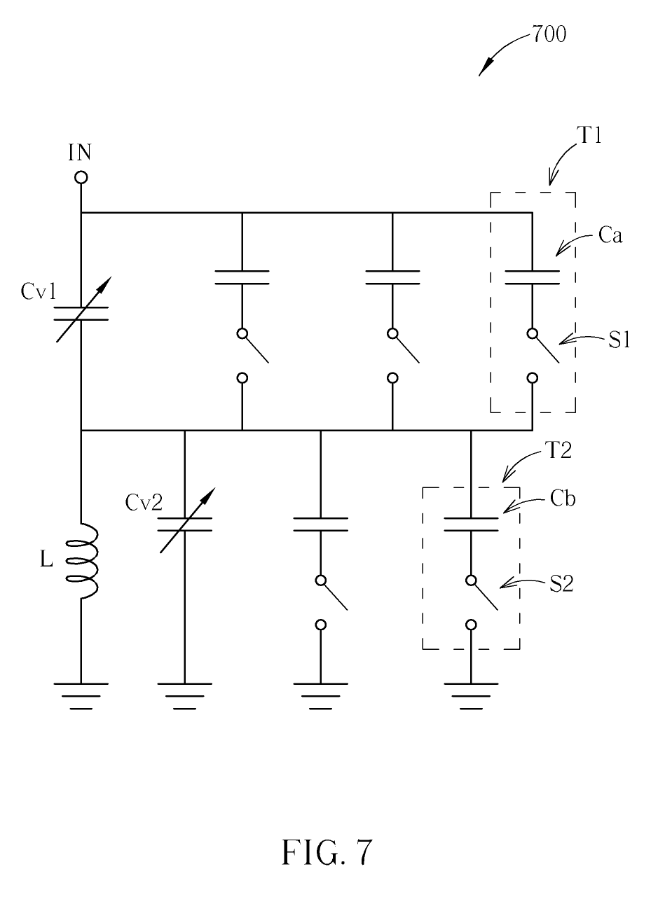

Please refer to FIG. 7. FIG. 7 is a diagram showing a fifth embodiment of a filter 700 of the present invention. As shown in FIG. 7, the filter 700 comprises a first varactor Cv1, a second varactor Cv2, a plurality of first capacitance adjusting units T1, a plurality of second capacitance adjusting units T2, and an inductor L. According to the above arrangement, the first varactor Cv1 can be utilized to fine tune a capacitance of an upper side of the filter 700, and the first capacitance adjusting unit T1 can be utilized to coarse tune the capacitance of the upper side of the filter 700 by controlling on and off states of the first switch S1 of the first capacitance adjusting unit T1. The second varactor Cv2 can be utilized to fine tune a capacitance of a lower side of the filter 700, and the second capacitance adjusting unit T2 can be utilized to coarse tune the capacitance of the lower side of the filter 700 by controlling on and off states of the second switch S2 of the second capacitance adjusting unit T2.

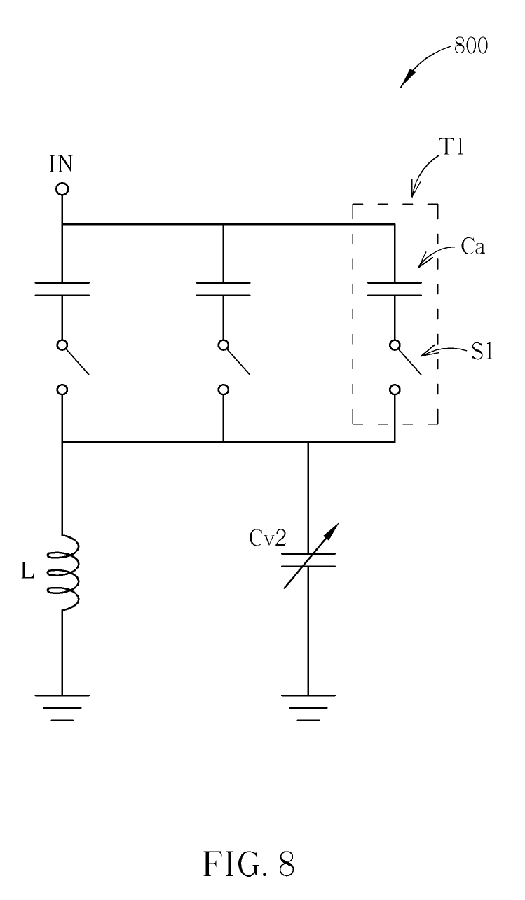

Please refer to FIG. 8. FIG. 8 is a diagram showing a sixth embodiment of a filter 800 of the present invention. As shown in FIG. 8, the filter 800 comprises a plurality of first capacitance adjusting units T1, a second varactor Cv2, and an inductor L. According to the above arrangement, the first capacitance adjusting unit T1 can be utilized to coarse tune a capacitance of an upper side of the filter 800 by controlling on and off states of the first switch S1 of the first capacitance adjusting unit T1, and the second varactor Cv2 can be utilized to fine tune a capacitance of a lower side of the filter 800.

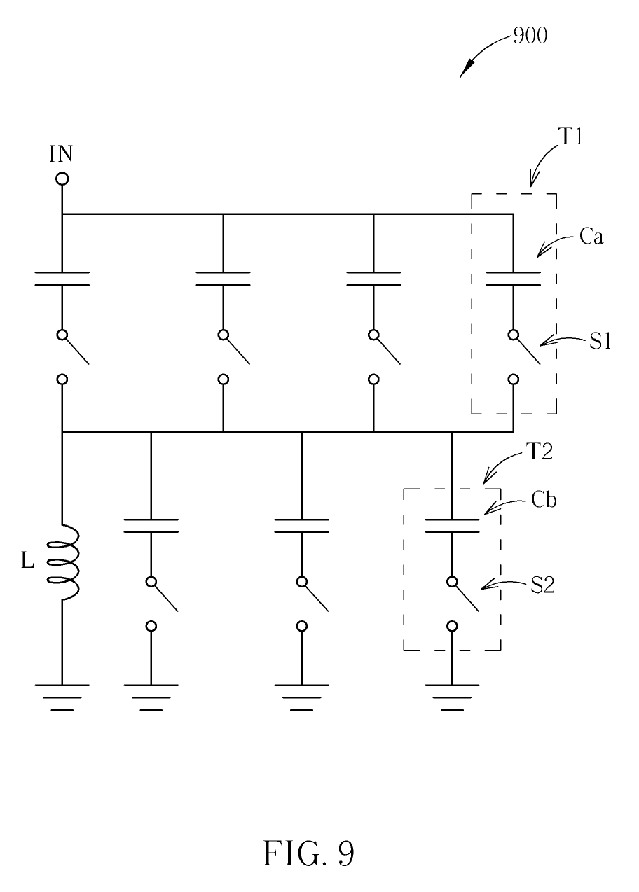

Please refer to FIG. 9. FIG. 9 is a diagram showing a seventh embodiment of a filter 900 of the present invention. As shown in FIG. 9, the filter 900 comprises a plurality of first capacitance adjusting units T1, a plurality of second capacitance adjusting units T2, and an inductor L. According to the above arrangement, the first capacitance adjusting unit T1 can be utilized to coarse tune a capacitance of an upper side of the filter 900 by controlling on and off states of the first switch S1 of the first capacitance adjusting unit T1, and the second capacitance adjusting unit T2 can be utilized to coarse tune a capacitance of a lower side of the filter 900 by controlling on and off states of the second switch S2 of the second capacitance adjusting unit T2.

The above filters can be utilized in several applications. For example, the filter can be applied to a low noise amplifier (LNA), or a low noise block (LNB) for adjusting their frequency responses. In manufacturing processes of the low noise block, the frequency response of the filter of the prior art is difficult to adjust after packaging. However, an inductance of an inductor may have some deviation, which may cause the frequency response of the packaged filter to be unable to meet specifications due to the deviation of the inductance. The filter of the present invention can compensate for an offset of the frequency response caused by the deviation of the inductance of the inductor by adjusting the capacitance of the upper side of the filter (that is, independently adjusting the zero frequency fz).

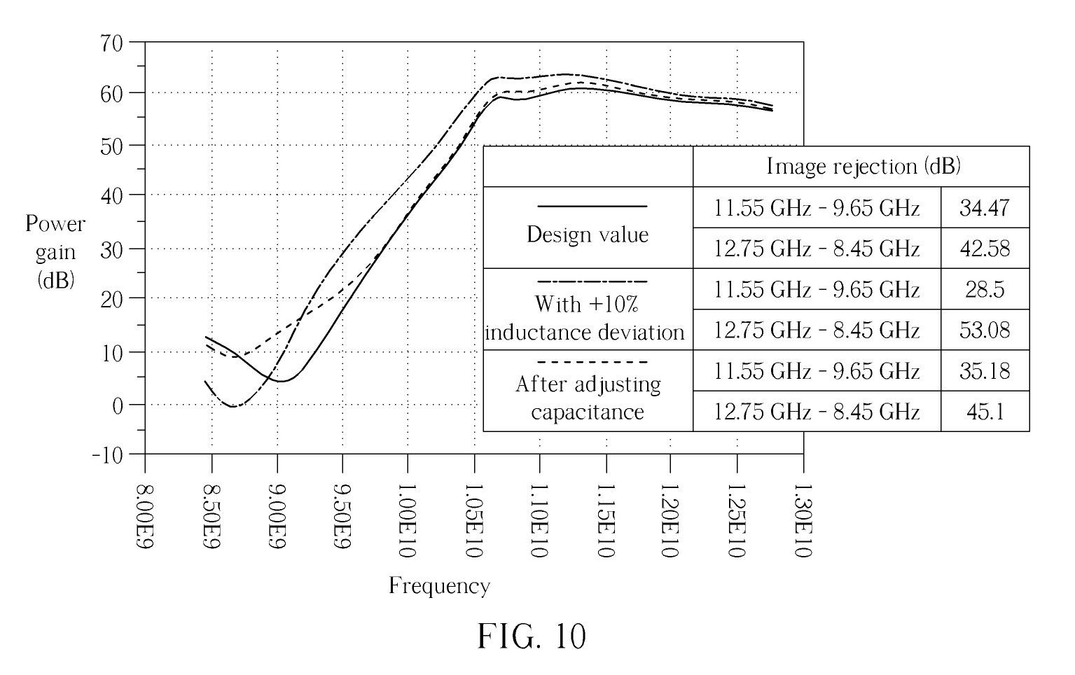

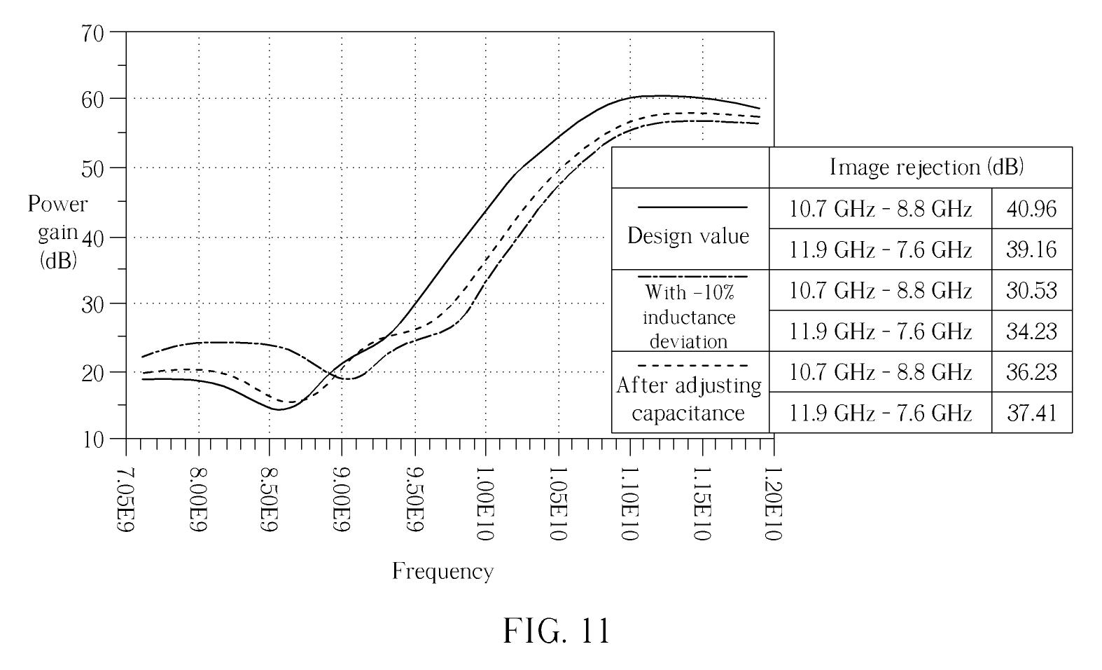

Please refer to FIG. 10 and FIG. 11. FIG. 10 is a diagram showing the filter of the present invention adjusting a frequency response of a high frequency band of a low noise block. FIG. 11 is a diagram showing the filter of the present invention adjusting a frequency response of a low frequency band of a low noise block. In the high frequency band, a local oscillation frequency of the low noise block is 10.6 Hz. Image rejection values of the low noise block are the difference between power gain at frequency of 11.55 Hz and power gain at frequency of 9.65 Hz, and the difference between power gain at frequency of 12.75 Hz and power gain at frequency of 8.45 Hz. In the low frequency band, the local oscillation frequency of the low noise block is 9.75 Hz. The image rejection values of the low noise block are the difference between power gain at frequency of 10.7 Hz and power gain at frequency of 8.8 Hz, and the difference between power gain at frequency of 11.9 Hz and power gain at frequency of 7.6 Hz. The larger the image rejection value is, the better the capability of the low noise block to reject interference will be. However, as shown in FIG. 10 and FIG. 11, the image rejection values of the low noise block deviate from design values when the inductance of the inductor has ±10% deviation. The image rejection values of the low noise block approach the design values after adjusting the capacitance of the upper side of the filter (such as adjusting a first varactor and/or a first capacitance adjusting unit).

In contrast to the prior art, the filter of the present invention can independently adjust the pole frequency and the zero frequency respectively in order to set the pole frequency and the zero frequency to the required positions. In addition, when the filter of the present invention is applied to the low noise block, the filter of the present invention can compensate for the offset of the frequency response caused by the deviation of the inductance of the inductor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A filter capable of adjusting frequency response, comprising:
a first varactor with a first end electrically connected to a signal input end;
a second varactor with a first end electrically connected to a second end of the first varactor, and a second end electrically connected to ground; and
an inductor with a first end electrically connected to the second end of the first varactor, and a second end electrically connected to ground.

2. The filter of claim 1 further comprising at least one capacitance adjusting unit, the capacitance adjusting unit comprising:
a capacitor with a first end electrically connected to the second end of the first varactor; and
a switch with a first end electrically connected to a second end of the capacitor, and a second end electrically connected to ground, the switch for electrically connecting the capacitor to ground when the switch is turned on.

3. A filter capable of adjusting frequency response, comprising:
a varactor with a first end electrically connected to a signal input end;
at least one capacitance adjusting unit, comprising:
a capacitor with a first end electrically connected to a second end of the varactor; and
a switch with a first end electrically connected to a second end of the capacitor, and a second end electrically connected to ground, the switch for electrically connecting the second end of the capacitor to ground when the switch is turned on; and
an inductor with a first end electrically connected to a second end of the varactor, and a second end electrically connected to ground.

4. A filter capable of adjusting frequency response, comprising:
a first varactor with a first end electrically connected to a signal input end;
a second varactor with a first end electrically connected to a second end of the first varactor, and a second end electrically connected to ground;
at least one first capacitance adjusting unit, comprising:
a first capacitor with a first end electrically connected to the signal input end; and
a first switch with a first end electrically connected to a second end of the first capacitor, and a second end electrically connected to the second end of the first varactor, the first switch for electrically connecting the second end of the first capacitor to the second end of the first varactor when the first switch is turned on;
at least one second capacitance adjusting unit, comprising:
a second capacitor with a first end electrically connected to the first end of the second varactor; and
a second switch with a first end electrically connected to a second end of the second capacitor, and a second end electrically connected to ground, the second switch for electrically connecting the second end of the second capacitor to ground when the second switch is turned on; and
an inductor with a first end electrically connected to the second end of the first varactor, and a second end electrically connected to ground.

5. A filter capable of adjusting frequency response comprising:
a first varactor with a first end electrically connected to a signal input end;
a second varactor with a first end electrically connected to a second end of the first varactor, and a second end electrically connected to ground;
at least one capacitance adjusting unit, comprising:
a capacitor with a first end electrically connected to the signal input end; and
a switch with a first end electrically connected to a second end of the capacitor, and a second end electrically connected to the second end of the first varactor, the switch for electrically connecting the second end of the capacitor to the second end of the first varactor when the switch is turned on; and
an inductor with a first end electrically connected to the second end of the first varactor, and a second end electrically connected to ground.

6. A filter capable of adjusting frequency response comprising:
a plurality of capacitance adjusting units, each capacitance adjusting unit comprising:
a capacitor with a first end electrically connected to a signal input end; and
a switch with a first end electrically connected to a second end of the capacitor, the switch for electrically connecting a second end of the capacitor to a second end of the switch when the switch is turned on;
a varactor with a first end electrically connected to the second end of the switch, and a second end electrically connected to ground; and
an inductor with a first end electrically connected to the second end of the switch, and a second end electrically connected to ground.

7. A filter capable of adjusting frequency response comprising:
a plurality of first capacitance adjusting units, each first capacitance adjusting unit comprising:
a first capacitor with a first end electrically connected to a signal input end; and
a first switch with a first end electrically connected to a second end of the first capacitor, the first switch for electrically connecting the second end of the first capacitor to a second end of the first switch when the first switch is turned on;
a plurality of second capacitance adjusting units, each second capacitance adjusting unit comprising:
a second capacitor with a first end electrically connected to the second end of the first switch; and
a second switch with a first end electrically connected to a second end of the second capacitor, and a second end electrically connected to ground, the second switch for electrically connecting the second end of the second capacitor to ground when the second switch is turned on; and
an inductor with a first end electrically connected to the second end of the first switch, and a second end electrically connected to ground.

8. A method for adjusting frequency response of a filter, the filter comprising a first capacitor with a first end electrically connected to a signal input end, a second capacitor with a first end electrically connected to a second end of the first capacitor, and a second end electrically connected to ground, and an inductor with a first end electrically connected to the second end of the first capacitor, and a second end electrically connected to the ground, the method comprising:
measuring a gain of the filter at a particular frequency; and
adjusting a capacitance of the first capacitor according to the gain of the filter at the particular frequency.

9. The method of claim 8, wherein measuring the gain of the filter at the particular frequency is measuring the gain of the filter at the particular frequency after the filter is packaged.

10. The method of claim 8, further comprising parallelly coupling a third capacitor to the first capacitor.
